(19) United States
(12) Patent Application Publication
(10) Pub. No.: US 2026/0293739 A1
(43) Pub. Date: Sep. 24, 2026

(54) SEMICONDUCTOR DEVICE AND MANUFACTURING METHOD FOR SEMICONDUCTOR DEVICE

(71) Applicant: Kioxia Corporation, Tokyo (JP)

(72) Inventor: Satoru TAKAKU, Yokohama (JP)

(73) Assignee: Kioxia Corporation, Tokyo (JP)

(21) Appl. No.: 19/249,119

(22) Filed: Jun. 25, 2025

(30) Foreign Application Priority Data
Mar. 20, 2025 (JP) 2025-046134

(51) Int. Cl. H01L 23/00

(52) U.S. Cl. CPC H10W 72/30; H10W 72/50; H10W 72/851; H10W 99/00; H10W 72/073; H10W 72/075; H10W 72/334; H10W 72/354; H10W 72/884; H10W 90/734; H10W 90/754

(57) ABSTRACT

A semiconductor device according to an embodiment includes a circuit board, a first semiconductor element provided on the circuit board via a first adhesive layer, and a first bonding wire connecting the circuit board and the first semiconductor element. A first distance is longer than a second distance. The first distance is a length between a connection surface between the first adhesive layer and the first semiconductor element and a location on the first adhesive layer on the furthest opposite side of the circuit board. The second distance is a length between a surface of the first semiconductor element on the opposite side of the circuit board and the connection surface between the first adhesive layer and the first semiconductor element.

### CROSS-REFERENCE TO RELATED APPLICATION

This application is based upon and claims the benefit of priority from Japanese Patent Application No. 2025-46134, filed on Mar. 20, 2025, the entire contents of which are incorporated herein by reference.

### FIELD

Embodiments described herein relate generally to a semiconductor device and a manufacturing method for a semiconductor device.

### BACKGROUND

In an ordinary semiconductor package with stacked NAND flash memory chips, chips such as controller chip are connected with a bonding wire on a circuit board.

### BRIEF DESCRIPTION OF THE DRAWINGS

FIG. 1 is a schematic cross-sectional diagram of a semiconductor device according to an embodiment;

FIG. 2 is schematic plan-view diagram of a semiconductor device according to an embodiment;

FIG. 3 is a schematic cross-sectional diagram of a semiconductor device according to an embodiment;

FIG. 4 is schematic plan-view diagram of a semiconductor device according to an embodiment;

FIG. 5 is a schematic cross-sectional diagram of a semiconductor device according to an embodiment;

FIG. 6 is a schematic cross-sectional diagram of a semiconductor device according to an embodiment;

FIG. 7 is a schematic cross-sectional diagram of a semiconductor device according to an embodiment;

FIG. 8 is a schematic cross-sectional diagram of a semiconductor device according to an embodiment;

FIG. 9 is a schematic cross-sectional diagram of a semiconductor device according to an embodiment;

FIG. 10 is a schematic cross-sectional diagram of a semiconductor device according to an embodiment;

FIG. 11 is a schematic cross-sectional diagram of a semiconductor device according to an embodiment;

FIG. 12 is a flowchart of a manufacturing method for a semiconductor device according to an embodiment;

FIG. 13 is a schematic diagram relating to a manufacturing method for a semiconductor device according to an embodiment;

FIG. 14 is a schematic diagram relating to a manufacturing method for a semiconductor device according to an embodiment;

FIG. 15 is a schematic diagram relating to a manufacturing method for a semiconductor device according to an embodiment;

FIG. 16 is a schematic diagram relating to a manufacturing method for a semiconductor device according to an embodiment;

FIG. 17 is a schematic diagram relating to a manufacturing method for a semiconductor device according to an embodiment;

FIG. 18 is a schematic cross-sectional diagram of a semiconductor device according to an embodiment;

FIG. 19 is a schematic diagram relating to a manufacturing method for a semiconductor device according to an embodiment;

FIG. 20 is a schematic diagram relating to a manufacturing method for a semiconductor device according to an embodiment;

FIG. 21 is a schematic diagram relating to a manufacturing method for a semiconductor device according to an embodiment;

FIG. 22 is a schematic cross-sectional diagram of a semiconductor device according to an embodiment;

FIG. 23 is a flowchart of a manufacturing method for a semiconductor device according to an embodiment;

FIG. 24 is a schematic diagram relating to a manufacturing method for a semiconductor device according to an embodiment;

FIG. 25 is a schematic diagram relating to a manufacturing method for a semiconductor device according to an embodiment;

FIG. 26 is a schematic diagram relating to a manufacturing method for a semiconductor device according to an embodiment; and

FIG. 27 is a schematic diagram relating to a manufacturing method for a semiconductor device according to an embodiment.

### DETAILED DESCRIPTION

A semiconductor device according to an embodiment includes a circuit board, a first semiconductor element provided on the circuit board via a first adhesive layer, and a first bonding wire connecting the circuit board and the first semiconductor element. A first distance is longer than a second distance. The first distance is a length between a connection surface between the first adhesive layer and the first semiconductor element and a location on the first adhesive layer on the furthest opposite side of the circuit board. The second distance is a length between a surface of the first semiconductor element on the opposite side of the circuit board and the connection surface between the first adhesive layer and the first semiconductor element.

Hereinafter, embodiments will be described with referring to drawings.

In this specification, several elements are given a plurality of expression examples. These expression examples are merely examples, and do not deny that the above-described elements are expressed by other expressions. An element to which a plurality of expressions is not given may also be expressed by another expression.

The drawings are schematic, and a relationship between a thickness and a plane dimension, a ratio between thicknesses of layers, and the like may be different from actual relationship and ratios. In addition, the drawings may include portions having different dimensional relationships and ratios. In the drawings, some reference numerals may be omitted.

In this specification, processes include not only independent processes but also combinations with other processes or treatments. Regarding numerical conditions in this document, if multiple numerical ranges are stated, the upper or lower limit values of one range can be replaced by those of another range. The upper and lower limit values mentioned in this document's numerical conditions can also be replaced with a condition specifying a numerical range combining both values.

### Fitst Embodiment

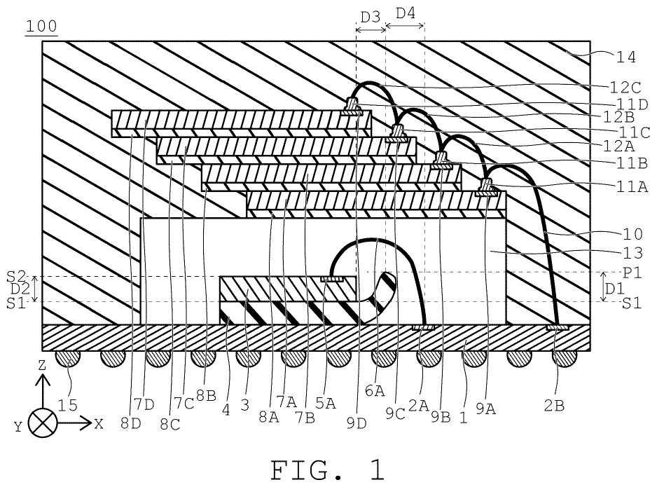

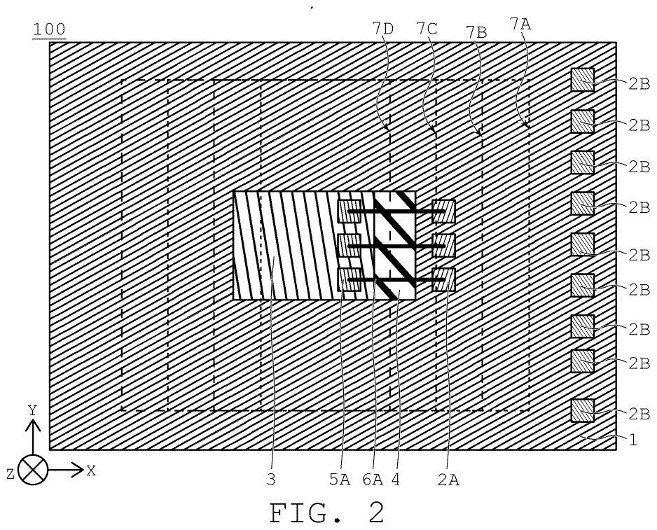

A first embodiment relates to a semiconductor device and a manufacturing method for thereof. FIG. 1 shows a schematic cross-sectional diagram of a semiconductor device 100. FIG. 2 shows schematic plan-view diagram of the semiconductor device 100 mainly illustrating a first semiconductor element 3. The schematic diagram in FIG. 1 is a schematic cross-sectional diagram at position A-A′ of the schematic diagram in FIG. 2. The semiconductor device 100 of this embodiment is more specifically a semiconductor package mounting a NAND flash memory chip, etc. It is preferable that the X direction, Y direction, and Z direction intersect each other and are mutually orthogonal.

The semiconductor device 100 is an example of a memory device. The semiconductor device includes a circuit board 1, a first semiconductor element 3, a first adhesive layer 4, a first bonding wire 6A, a second semiconductor element 7A, a third semiconductor element 7B, a fourth semiconductor element 7C, a fifth semiconductor element 7D, a second adhesive layer 8A, a third adhesive layer 8B, a fourth adhesive layer 8C, a fifth adhesive layer 8D, a second bonding wire 10, a third bonding wire 12A, a fourth bonding wire 12B, a fifth bonding wire 12C, a first encapsulation resin 13, a second encapsulation resin 14, and soldering balls 15.

The schematic diagram of FIG. 2 illustrates a partial configuration of the semiconductor device 100 of FIG. 1. The locations of the second semiconductor element 7A, the third semiconductor element 7B, the fourth semiconductor element 7C, and the fifth semiconductor element 7D are indicated by broken lines.

The circuit board 1 is a supporting substrate for the first semiconductor element 3 and the others. Specifically, the circuit board 1 is a multi-layered circuit board. The first semiconductor element 3 is provided on the first surface side of the circuit board 1. Hemispherical electrodes including the soldering balls 15 for external connection of the semiconductor device 100 are provided on the second surface side opposite to the first surface of the circuit board 1.

A first pad 2A and a third pad 2B are included in the circuit board 1 on the first surface side shown in FIG. 1. The first bonding wire 6A is connected to the first pad 2A. The second bonding wire 10 is connected to the third pad 2B.

The first semiconductor element 3 is provided on the circuit board 1 via the first adhesive layer 4. The first semiconductor element 3 is, for example, a bare chip. The first semiconductor element 3 is covered with the first encapsulation resin 13. The first semiconductor element 3 is connected the circuit board 1 via the first adhesive layer 4. When the semiconductor device 100 is a memory device, for example, the first semiconductor element 3 is a controller chip, and the second semiconductor element 7A is a semiconductor memory chip. The controller chip controls reading, writing and erasing for the semiconductor memory chip.

The first semiconductor element 3 and the circuit board 1 is connected by the first bonding wire 6A. The first semiconductor element 3 includes a second pad 5A on the opposite side of the circuit board 1. The first bonding wire 6A is connected to the second pad 5A.

The first adhesive layer 4 is an insulating layer disposed between the circuit board 1 and the first semiconductor element 3. The circuit board 1, the first adhesive layer 4, and the first semiconductor element 3 are stacked. The first adhesive layer 4 includes resin composition such as acryl resin, epoxy resin, and the like. The first adhesive layer 4 includes acrylic resin as a main component. The first adhesive layer 4 is, for example, a cured adhesive layer. Specifically, the first adhesive layer 4 is a layer of cured resin of a die-bonding adhesive layer including DAF which is stuck to the first semiconductor element 3.

The first adhesive layer 4 preferably includes 20 [wt %] or more of acrylic resin among its organic compounds. The first adhesive layer 4 more preferably includes 25 [wt %] or more of acrylic resin among its organic compounds. The first adhesive layer 4 even more preferably includes 30 [wt %] or more of acrylic resin among its organic compounds.

The first adhesive layer 4 preferably includes 20 [wt %] or more and 50 [wt %] or less of acrylic resin among its organic compounds. The first adhesive layer 4 more preferably includes 20 [wt %] or more and 40 [wt %] or less of acrylic resin among its organic compounds. The first adhesive layer 4 even more preferably includes 30 [wt %] or more and 40 [wt %] or less of acrylic resin among its organic compounds.

The thickness of the first adhesive layer 4 (the distance between the circuit board 1 and the first semiconductor element 3) is 20 [μm] or more and 200 [μm] or less. The thickness of the first adhesive layer 4 is preferably 1 times or more and 5 times or less the thickness of the first semiconductor element 3, and more preferably 1.5 times or more and 5 times or less the thickness of the first semiconductor element 3.

The first adhesive layer 4 includes a portion which does not overlap with the first semiconductor 3 on the first pad 2A side in a stacking direction of the first adhesive layer 4 and the first semiconductor element 3. FIG. 2 illustrates the portion of the first adhesive layer 4, the portion does not overlap with the first semiconductor 3 on the first pad 2A side in the stacking direction of the first adhesive layer 4 and the first semiconductor element 3

The volume of the portion of the first adhesive layer 4 which does not overlap with the first semiconductor 3 on the first pad 2A side in a stacking direction of the first adhesive layer 4 and the first semiconductor element 3 is preferably smaller than a portion of the first adhesive layer 4 which overlaps with the first semiconductor 3 on the first pad 2A side in the stacking direction of the first adhesive layer 4 and the first semiconductor element 3.

Accordingly, the portion of the first adhesive layer 4 which does not overlap with the first semiconductor 3 on the first pad 2A side is located higher than the surface of the first semiconductor element 3 on the opposite side of the circuit board 1 in the cross-sectional direction of FIG. 1.

A distance D1 (first distance) which is a length between a connection surface S1 (starting point) between the first adhesive layer 4 and the first semiconductor element 3 and a location P1 (ending point) on the first adhesive layer 4 on the furthest opposite side of the circuit board 1 is preferably longer than a distance D2 (second distance) which is a length between a surface S2 (starting point) of the first semiconductor element 3 on the opposite side of the circuit board 1 and the connection surface S1 (ending point) between the first adhesive layer 4 and the first semiconductor element 3 in the stacking direction of the first adhesive layer 4 and the first semiconductor element 3.

The distance D1 is preferably longer than the distance D2 in the stacking direction of the first adhesive layer 4 and the first semiconductor element 3, and the difference (D1-D2) between the distance D1 and the distance D2 in the stacking direction of the first adhesive layer 4 and the first semiconductor element 3 is preferably 1 [μm] or more and 60 [μm] or less, more preferably 1 [μm] or more and 40 [μm] or less, and even more preferably 1 [μm] or more and 20 [μm] or less.

A distance D3 (third distance) is a length between the location P1 (starting point) and the side surface (ending point) of the first semiconductor element 3 on the first pad 2A side is preferably 0 [μm] or more and 1800 [μm] or less, more preferably 0 [μm] or more and 1500 [μm] or less, and even more preferably 0 [μm] or more and 1200 [μm] or less.

A distance D4 (fourth distance) is a length between the location P1 (starting point) and the connection point (ending point) of the first pad 2A and the first bonding wire 6A is preferably 200 [μm] or more and 2000 [μm] or less, more preferably 250 [μm] or more and 1900 [μm] or less, and even more preferably 300 [μm] or more and 1800 [μm] or less.

When the protrusion portion has a curved surface, the curved surface has capability of preventing localized stress applied to the first bonding wire 6A when the first bonding wire 6A comes into contact with the first adhesive layer 4.

FIG. 1 illustrates the semiconductor device 100 in which the first bonding wire 6A strides over a portion of the first adhesive layer 4 protruding (overhanging) from one edge of the first semiconductor element 3. Moreover, embodiments also includes configurations in which the first adhesive layer 4 protrudes (overhangs) from two edges, three edges, and all edges among the peripheral edges of the first semiconductor element 3.

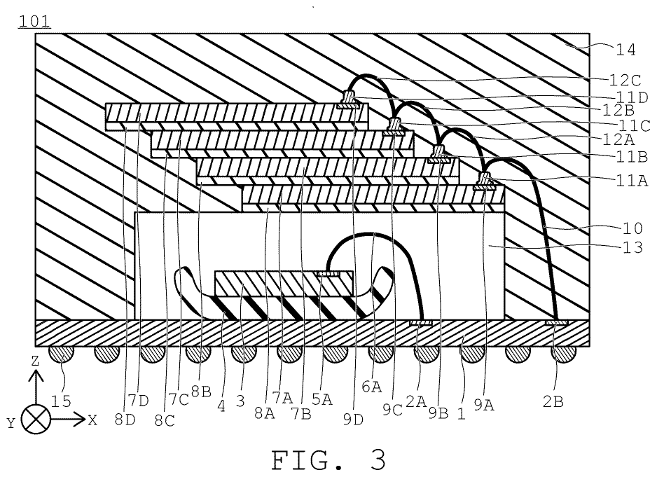

FIG. 3 illustrates a schematic cross-sectional diagram of the semiconductor device 101 with the first adhesive layer 4 protruding from all edges among the peripheral edges of the first semiconductor element 3. FIG. 4 illustrates a schematic plan-view diagram of the semiconductor device 101. The protrusion, preferably at least where the first bonding wire 6A strides over the first adhesive layer 4, more preferably a plurality of or every protrusion satisfies the ranges of D1 and the others.

The first encapsulation resin 13 encapsulates the first semiconductor element 3. The first encapsulation resin 13 uses resins such as epoxy, phenolic, polyimide, polyamide, acrylic, PBO, silicone, benzocyclobutene, mixtures thereof, and composite materials. Examples of epoxy resins are not particularly limited. Bisphenol type epoxy resins such as bisphenol A type, bisphenol F type, bisphenol AD type, and bisphenol S type, novolac type epoxy resins such as phenol novolac type and cresol novolac type, resorcinol type epoxy resin, aromatic epoxy resins such as trisphenol methane triglycidyl ether, naphthalene type epoxy resin, fluorene type epoxy resin, dicyclopentadiene type epoxy resin, polyether-modified epoxy resin, benzophenone type epoxy resin, aniline type epoxy resin, NBR modified epoxy resin, CTBN modified epoxy resin, and their hydrogenated products are examples of the epoxy resin. Among these, naphthalene type epoxy resin and dicyclopentadiene type epoxy resin are preferable because of their good adhesion to Si. Benzophenone type epoxy resin is also preferable because it easily achieves fast curing. These epoxy resins may be used alone or in combination of two or more. The first encapsulation resin 13 may contain fillers such as silica, alumina or the like. The first encapsulation resin 13 is not mainly acrylic resin. The ratio of acrylic resin contained in the first encapsulation resin 13 is preferably lower than the ratio of acrylic resin contained in the first adhesive layer 4.

The first bonding wire 6A connects the circuit board 1 and the first semiconductor element 3. Specifically, the first bonding wire 6A connects the first pad 2A of the circuit board 1 and the second pad 5A of the first semiconductor element 3. Bonding wires including the first bonding wire 6A includes one or more metal elements selected from the group consisting of Au, Ag, and Cu and may coated by Pd or the like.

The second semiconductor element 7A is provided on the first encapsulation resin 13 via the second adhesive layer 8A. The second semiconductor element 7A is, for example, a NAND flash memory chip. The second semiconductor element 7A includes a fourth pad 9A. The fourth pad 9A of the second semiconductor element 7A and the third pad 2B of the circuit board 1 is connected by the second bonding wire 10. A first bump 11A is provided on the fourth pad 9A. The first bump 11A connects the second bonding wire 10 and the third bonding wire 12A. Bumps including the first bump 11A are provided on any pad.

The third semiconductor element 7B is provided on the second semiconductor element 7A via the third adhesive layer 8B. The third semiconductor element 7B is, for example, a NAND flash memory chip with the same or similar circuit configuration as the second semiconductor element 7A. The third semiconductor element 7B includes a fifth pad 9B. The fifth pad 9B of the third semiconductor element 7B and the fourth pad 9A of the second semiconductor element 7A are connected by the third bonding wire 12A. A second bump 11B is provided on the fifth pad 9A. The second bump 11B connects the third bonding wire 12A and the fourth bonding wire 12B.

The fourth semiconductor element 7C is provided on the third semiconductor element 7B via the fourth adhesive layer 8C. The fourth semiconductor element 7C is, for example, a NAND flash memory chip with the same or similar circuit configuration as the second semiconductor element 7A. The fourth semiconductor element 7C includes a sixth pad 9C. The sixth pad 9C of the fourth semiconductor element 7C and the fifth pad 9B of the third semiconductor element 7B are connected by the fourth bonding wire 12B. A third bump 11C is provided on the sixth pad 9C. The third bump 9C connects the fourth bonding wire 12B and the fifth bonding wire 12C.

The fifth semiconductor element 7D is provided on the fourth semiconductor element 7C via the fifth adhesive layer 8D. The fifth semiconductor element 7D, for example, a NAND flash memory chip with the same or similar circuit configuration as the second semiconductor element 7A. The fifth semiconductor element 7D includes a seventh pad 9D. The seventh pad 9D of the fifth semiconductor element 7D and the sixth pad 9C of the fourth semiconductor element 7C are connected by the fifth bonding wire 12C. A fourth bump 11D is provided on the seventh pad 9D.

As shown in FIG. 1, when two or more semiconductor elements with the same or similar circuit configuration, such as the second semiconductor element 7A, the third semiconductor element 7B, the fourth semiconductor element 7C, and the fifth semiconductor element 7D are included, the semiconductor elements with the same or similar circuit configuration are stacked preferably in the Z-direction with an offset in the X direction.

The second encapsulation resin 14 encapsulates the second semiconductor element 7A and the other semiconductor elements. The second encapsulation resin 14 uses resins such as epoxy, phenolic, polyimide, polyamide, acrylic, PBO, silicone, benzocyclobutene, mixtures thereof, and composite materials. Examples of epoxy resins are not particularly limited. Bisphenol type epoxy resins such as bisphenol A type, bisphenol F type, bisphenol AD type, and bisphenol S type, novolac type epoxy resins such as phenol novolac type and cresol novolac type, resorcinol type epoxy resin, aromatic epoxy resins such as trisphenol methane triglycidyl ether, naphthalene type epoxy resin, fluorene type epoxy resin, dicyclopentadiene type epoxy resin, polyether-modified epoxy resin, benzophenone type epoxy resin, aniline type epoxy resin, NBR modified epoxy resin, CTBN modified epoxy resin, and their hydrogenated products are examples of the epoxy resin. Among these, naphthalene type epoxy resin and dicyclopentadiene type epoxy resin are preferable because of their good adhesion to Si. Benzophenone type epoxy resin is also preferable because it easily achieves fast curing. These epoxy resins may be used alone or in combination of two or more. The first encapsulation resin 13 may contain fillers such as silica or alumina. The second encapsulation resin 14 is not mainly acrylic resin. The ratio of acrylic resin contained in the second encapsulation resin 14 is preferably lower than the ratio of acrylic resin contained in the first adhesive layer 4.

Since the distance D1 is longer than the distance D2 in the stacking direction of the first adhesive layer 4 and the first semiconductor element 3, physical contact between the first bonding wire 4 and the peripheral edge(s) of the first semiconductor element 3 may be prevented by the first adhesive layer 4 functioning as a pillar when the first bonding wire 6A is deformed, crushed, or the like. When the first encapsulation resin 13 is FOD (Film Over Die), the first bonding wire 6A may be easily deformed when the first semiconductor element 3 is encapsulated by FOD. However, the protruding portion of the first adhesive layer 4 acts as a pillar, effectively reducing the amount of deformation experienced by the first bonding wire 6A. It contribute to reduce possibility of disconnection of the first bonding wire 6A or the like, resulting in improving reliability of the semiconductor device 100.

FIG. 5 illustrate a schematic diagram of a semiconductor device 102. The semiconductor device 102 is another variety of the semiconductor device 100. The semiconductor device 102 includes the configuration of the semiconductor device 100. In the semiconductor device 102 the circuit board 1 also includes an eighth pad 2C, the first semiconductor element 3 also includes an eighth pad 5B, and a sixth bonding wire 6B is also included.

The first bonding wire 6A and the sixth bonding wire 6B extends to different directions. When additional bonding wire extending to a direction different from the first bonding wire 6A connects to the first semiconductor element 3, it is preferable that the first adhesive layer 4 further includes such a protrusion on the eighth pad 2C side at higher side from the connection surface toward the opposite side of the circuit board 1 in which the protrusion extends to the direction of the additional bonding wire.

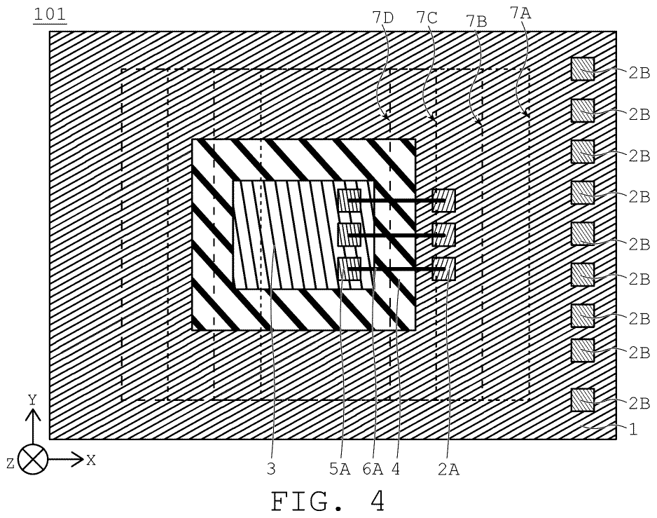

FIG. 6 illustrates a schematic diagram of a semiconductor device 103. The semiconductor device 103 is another variety of the semiconductor device 100. The second semiconductor element 7A of the semiconductor device 103 is provided on the circuit board 1 but not on the first encapsulation resin 13 encapsulating the first semiconductor element 3. The components of the semiconductor device 103 are entirely encapsulated by the first encapsulation resin 13 but not the second encapsulation resin 14. Except for the above, the semiconductor device 103 includes the configuration similar to that of the semiconductor device 100.

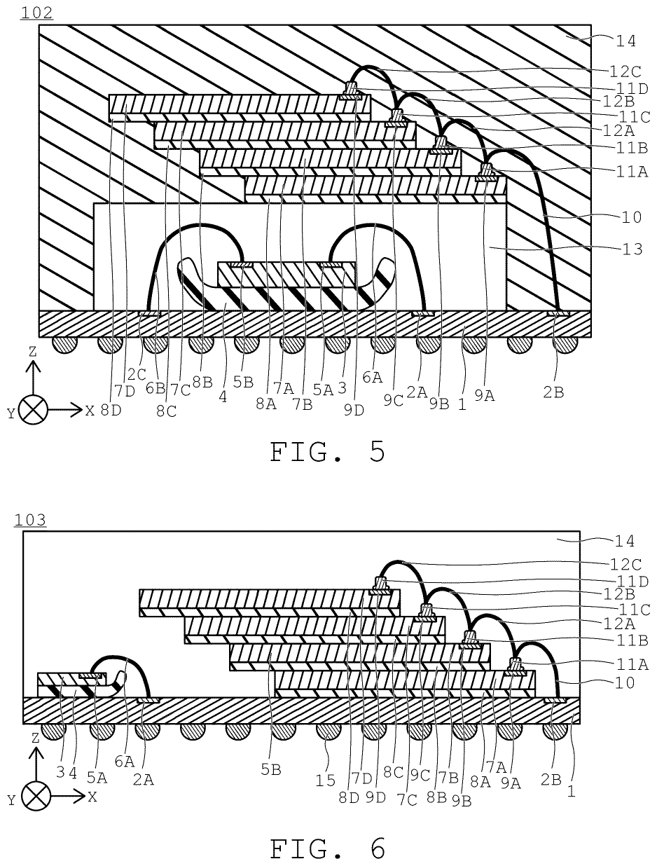

FIG. 7 illustrates a schematic diagram of a semiconductor device 104. The semiconductor device 104 is another variety of the semiconductor device 100. The semiconductor device includes the circuit board 1, a sixth semiconductor element 3A, a sixth adhesive layer 4A, a seventh semiconductor element 3B, a seventh adhesive layer 4B, an eighth semiconductor element 3C, an eighth adhesive layer 4C, a ninth semiconductor element 3D, a ninth adhesive layer 4D, a seventh bonding wire 6C, an eighth bonding wire 6D, a ninth bonding wire 6E, a tenth bonding wire 6F, the first encapsulation resin 13, the soldering balls 15, a tenth semiconductor element 16, an electrically conductive adhesive 17, and an insulating layer 18. The difference between the semiconductor device 104 and the semiconductor device 100 will be described.

The circuit configuration of the sixth semiconductor element 3A is similar or equivalent to the circuit configuration of the second semiconductor element 7A. The sixth semiconductor element 3A is provided on the circuit board 1 via the sixth adhesive layer 4A which is similar or equivalent to the first adhesive layer 4. A ninth pad 5C of the sixth semiconductor element 3A and the third pad 2B of the circuit board 1 are connected by the seventh bonding wire 6C.

The distance is a length between a connection surface (starting point) between the sixth adhesive layer 4A which is similar or equivalent to the first adhesive layer 4 and the sixth semiconductor element 3A and a location (ending point) the sixth semiconductor element 3A on the furthest opposite side of the circuit board 1, which is corresponding to the distance D1. The distance is a length between a surface (starting point) of the sixth semiconductor element 3A on the opposite side of the circuit board 1 and the connection surface (ending point) between the sixth adhesive layer 4A and the sixth semiconductor element 3A, which is corresponding to the distance D2.

The circuit configuration of the seventh semiconductor element 3B is similar or equivalent to the circuit configuration of the second semiconductor element 7A. The seventh semiconductor element 3B is provided on the sixth semiconductor element 3A via the seventh adhesive layer 4B which is similar or equivalent to the first adhesive layer 4. A tenth pad 5D of the seventh semiconductor element 3B and the ninth pad 5C of the sixth semiconductor element 3A are connected by the eighth bonding wire 6D.

The distance is a length between a connection surface (starting point) between the seventh adhesive layer 4B which is similar or equivalent to the first adhesive layer 4 and the seventh semiconductor element 3B and a location (ending point) on the seventh semiconductor element 3B on the furthest opposite side of the circuit board 1, which is corresponding to the distance D1 (not shown in drawings). The distance is a length between a surface (starting point) of the seventh semiconductor element 3B on the opposite side of the circuit board 1 and the connection surface (ending point) between the seventh adhesive layer 4B and the seventh semiconductor element 3B, which is corresponding to the distance D2 (not shown in drawings).

A fifth bump 11E is provided on the ninth pad 5C, and the fifth bump 11E connects the seventh bonding wire 6C and the eighth bonding wire 6D. A sixth bump 11F is provided on the tenth pad 5D, and the sixth bump 11F connects to the eighth bonding wire 6D. The fifth bump 11E is corresponding to the first bump 11A. The sixth bump 11F is corresponding to the second bump 11B.

The circuit configuration of the eighth semiconductor element 3C is similar or equivalent to the circuit configuration of the second semiconductor element 7A. The eighth semiconductor element 3C is provided on the circuit board 1 via the eighth adhesive layer 4C which is similar or equivalent to the first adhesive layer 4. An eleventh pad 5E of the sixth semiconductor element 3A and a pad 2D of the circuit board 1 are connected by the ninth bonding wire 6E.

The distance is a length between a connection surface (starting point) between the eighth adhesive layer 4C which is similar or equivalent to the first adhesive layer 4 and the eighth semiconductor element 3C and a location (ending point) on the eighth semiconductor element 3C on the furthest opposite side of the circuit board 1, which is corresponding to the distance D1. The distance is a length between a surface (starting point) of the eighth semiconductor element 3C on the opposite side of the circuit board 1 and the connection surface (ending point) between the eighth adhesive layer 4C and the eighth semiconductor element 3C, which is corresponding to the distance D2.

The circuit configuration of the ninth semiconductor element 3D is similar or equivalent to the circuit configuration of the second semiconductor element 7A. The ninth semiconductor element 3D is provided on the eighth semiconductor element 3C via the ninth adhesive layer 4D which is similar or equivalent to the first adhesive layer 4. A twelfth pad 5F of the ninth semiconductor element 3D and the eleventh pad 5E of the eighth semiconductor element 3C are connected by the tenth bonding wire 6F.

The distance is a length between a connection surface (starting point) between the ninth adhesive layer 4D which is similar or equivalent to the first adhesive layer 4 and the ninth semiconductor element 3D and a location (ending point) on the ninth semiconductor element 3D on the furthest opposite side of the circuit board 1, which is corresponding to the distance D1 (not shown in drawings). The distance is a length between a surface (starting point) of the ninth semiconductor element 3D on the opposite side of the circuit board 1 and the connection surface (ending point) between the ninth adhesive layer 4D and the ninth semiconductor element 3B, which is corresponding to the distance D2 (not shown in drawings).

A seventh bump 11G is provided on the eleventh pad 5E, and the seventh bump 11G connects the ninth bonding wire 6E and the tenth bonding wire 6F. A eighth bump 11H is provided on the twelfth pad 5F, and the eighth bump 11H connects to the tenth bonding wire 6F. The seventh bump 11G is corresponding to the third bump 11C. The eighth bump 11H is corresponding to the second bump 11B.

The first encapsulation resin 13 encapsulates the sixth semiconductor element 3A, the seventh semiconductor element 3B, the eighth semiconductor element 3C, the ninth semiconductor element 3D, and a tenth semiconductor element 16.

The tenth semiconductor element 16 is provided on the circuit board 1. The circuit configuration of the tenth semiconductor element 16 is similar or equivalent to the configuration of the first semiconductor element 3. The tenth semiconductor element 16 is a flip-chip type, and is connected to a thirteenth pad 2E on the circuit board 1 by the electrically conductive adhesive. The insulating layer 18 is also known as an underfill, fills the gap between the tenth semiconductor element 16 and the circuit board 1. The second encapsulation resin 14 is not mainly acrylic resin.

A semiconductor device 104 of the schematic diagram of FIG. 7 has a configuration in which the sixth adhesive layer 4A has a protrusion on the seventh bonding wire 6C side, the seventh adhesive layer 4B has a protrusion on the eighth bonding wire 6D side, the eighth adhesive layer 4C has a protrusion on the ninth bonding wire 6E side, and the ninth adhesive layer 4D has a protrusion on the tenth bonding wire 6F side, but not limited thereof. For example, a configuration in which the sixth adhesive layer 4A and the eighth adhesive layer 4C which are located at the lowest level have the protrusion but the seventh adhesive layer 4B and the ninth adhesive layer 4D do not have such protrusion is included in the embodiments.

FIG. 8 shows a schematic diagram of a semiconductor device 105. The semiconductor device 106 is another variety of the semiconductor device 100. The adhesive layer 4 of the semiconductor device 105 is in direct contact with a side surface of the first semiconductor element 3. With the exception of the adhesive layer 4 directly contacting the side surface of the first semiconductor element 3, the semiconductor device 106 includes a configuration similar to that of the semiconductor device 100.

The first adhesive layer 4 is positioned at a height higher than the edges of the surface on the side opposite the circuit board 1 of the first semiconductor element 3 in the stacking direction of layers. Thus, the first adhesive layer 4 is in direct contact with an edge of the surface of the first semiconductor element 3 on the opposite side of the circuit board 3.

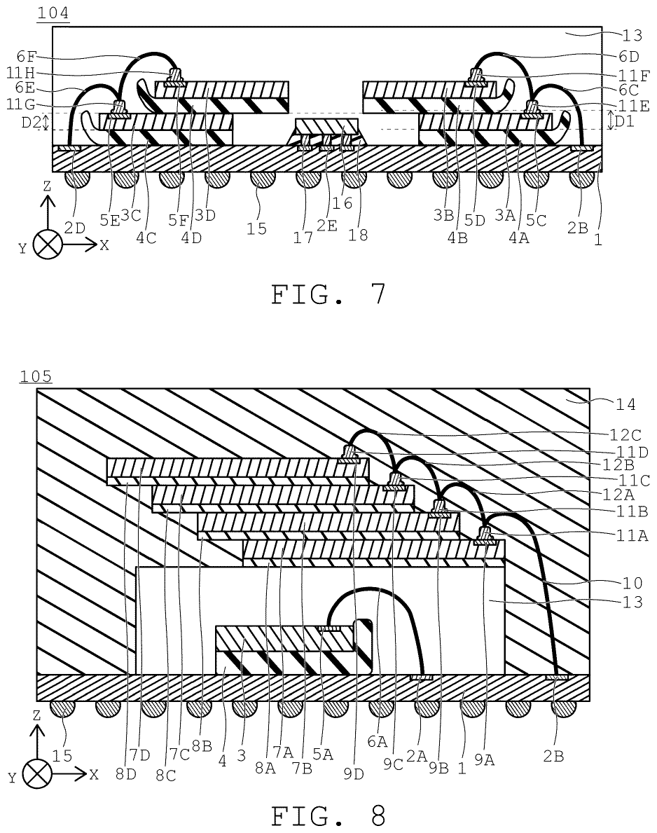

FIG. 9 shows a schematic diagram of a semiconductor device 106. The semiconductor device 106 is another variety of the semiconductor device 100. The circuit board 1 of the semiconductor device 106 has one or more protrusions. With the exception of the protrusion of the circuit board 1, the semiconductor device 106 includes a configuration similar to that of the semiconductor device 100.

The first adhesive layer 4 may be curved to the side opposite the circuit board 1 by, for example, forming the protrusion on the surface of the circuit board 1 using resist.

The first adhesive layer 4 is positioned at a height higher than the edges of the surface on the side opposite the circuit board 1 of the first semiconductor element 3.

FIG. 10 shows a schematic diagram of a semiconductor device 107. The semiconductor device 108 is another variation of the semiconductor device 100. The circuit board 1 of the semiconductor device 107 has one or more recesses and one or more protrusions. Except for the circuit board 1 having the recesses and the protrusions, the semiconductor device 107 is similar to the semiconductor device 100.

It is preferable that recesses and protrusions on the surface of the circuit board 1 be formed using resist to bend the first adhesive layer 4 towards the side opposite the circuit board 1 or guide the first adhesive layer 4 in the direction of the first pad 2A.

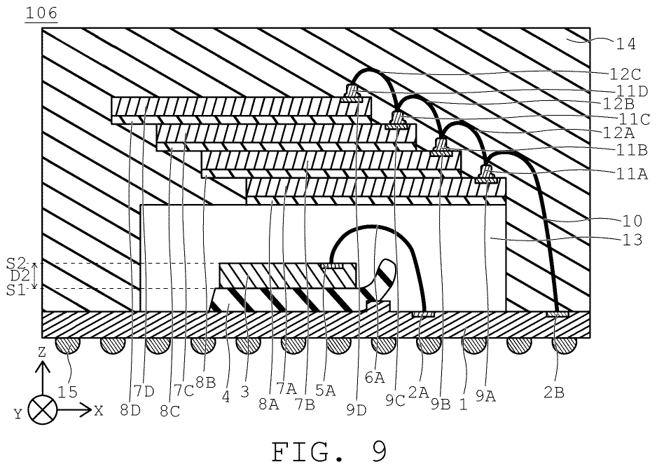

FIG. 11 shows a schematic diagram of the semiconductor device 108. The semiconductor device 108 is another variation of the semiconductor device 105. The circuit board 1 of the semiconductor device 109 has one or more protrusions. Except for the circuit board 1 having protrusions, the semiconductor device 108 is similar to the semiconductor device 100.

It is preferable that the height of the protrusion on the circuit board 1 directly below the first semiconductor element 3 be smaller than the thickness of the first adhesive layer 4. One or more protrusions with a height greater than the thickness of the first adhesive layer 4 may also be provided on the circuit board 1 outside the area directly below the first semiconductor element 3.

The protrusion of the circuit board 1 is preferably in direct contact with the first adhesive layer 4.

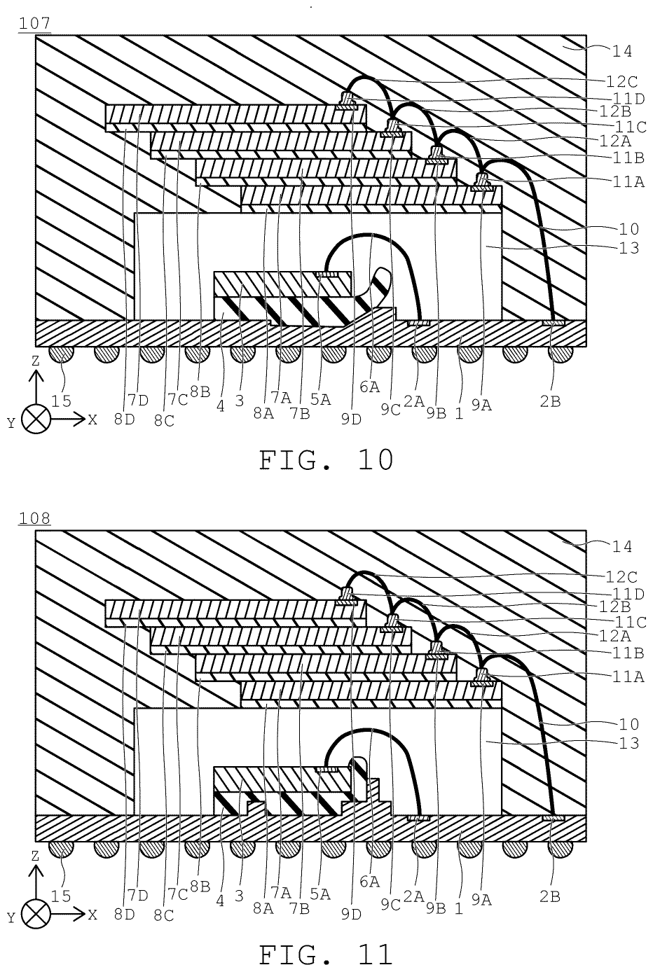

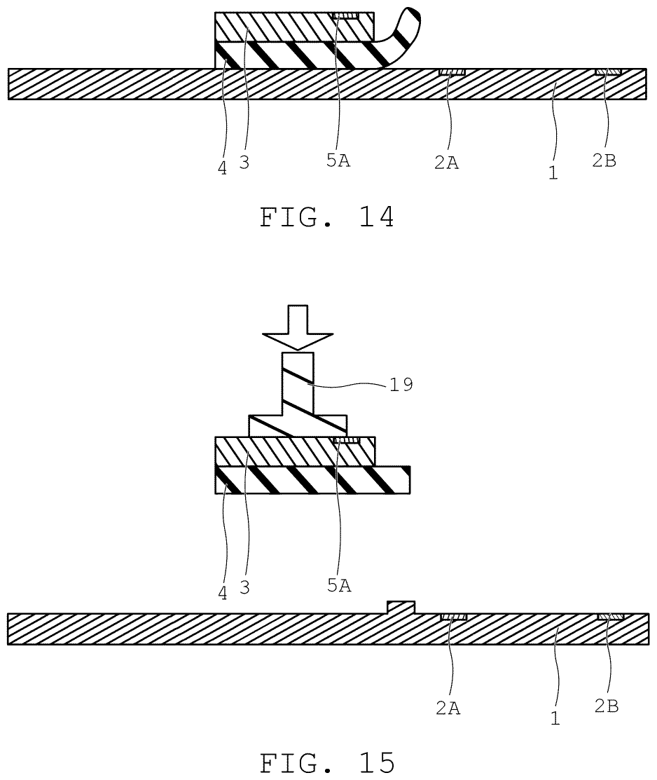

Next, a manufacturing method for the semiconductor device 100 will be described. FIG. 12 shows a flowchart of the manufacturing method for the semiconductor device 100. FIG. 13 to FIG. 17 show schematic diagrams related to the manufacturing method for the semiconductor device 100.

The manufacturing method for the semiconductor device 100 includes adhering the first semiconductor element 3 on the circuit board 1 via the first adhesive layer 4, and forming the first bonding wire 6A which connects the first semiconductor element 3 and the circuit board 1. The adhering is procced so that a first distance D1 becomes longer than a second distance D2. The first distance D1 is a length between the connection surface S1 (starting point) between the first adhesive layer 4 and the first semiconductor element 3 and the location P1 (ending point) on the opposite side of the first adhesive layer 4 on the furthest opposite side of the circuit board 1. The second distance D2 is a length between the surface S1 (starting point) of the first semiconductor element 3 on the opposite side of the circuit board 1 and the connection surface S1 (ending point) between the first adhesive layer 4 and the first semiconductor element 3.

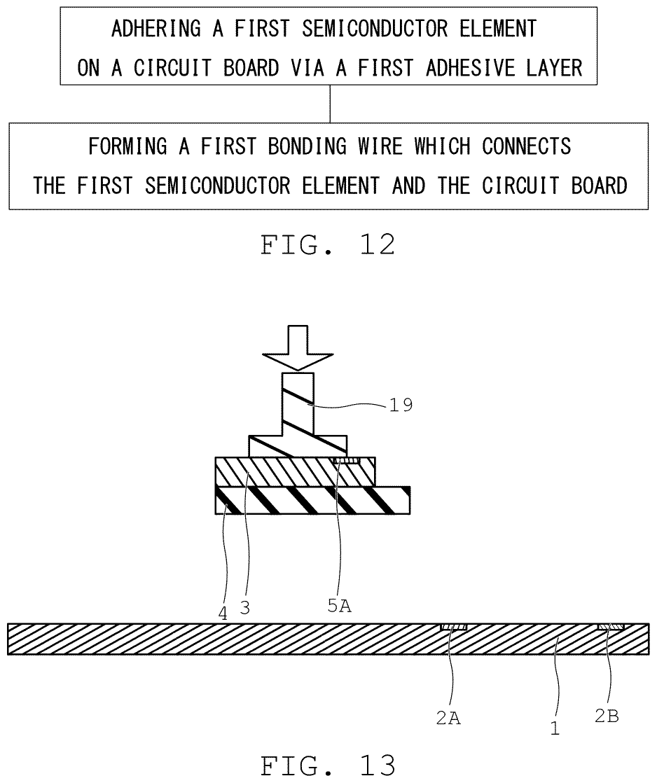

The adhering the first semiconductor element 3 on the circuit board 1 via the first adhesive layer 4 will be described referring to the schematic diagram of FIG. 13. The schematic diagram in FIG. 13 shows a laminated body of the first semiconductor element 3 and the first adhesive layer (pre-cured) 4 mounted on a jig 19 (e.g., collet) and pressed onto the circuit board 1 to place the laminated body on the circuit board 1. At this time, since the portion of the first adhesive layer 4 protrudes toward the first pad 2A (the portion on the first pad 2A side extending in a direction to the second pad 5A from the center of the first semiconductor element 3, which is not directly in contact with the first semiconductor element 3) exists and causes to be bended toward the opposite side of the circuit board 1. The member shown in the schematic diagram of FIG. 14 is thus obtained by deformation of the first adhesive layer 4.

The surface of the jig 19 on the side of contacting to the first semiconductor element 3 is preferably smaller than the surface of the first semiconductor element 3 opposite to the circuit board 1. For example, as shown in the schematic diagram of the semiconductor device 108 in FIG. 11, when at least a part of one or more edges of the first semiconductor element 3 is covered by the first adhesive layer 4, the jig 19 does not hinder the deformation of the first adhesive layer 4. Since the edges of the first semiconductor element 3 are sharp, it is preferable that the first bonding wire 6A does not come into contact with the edges of the first semiconductor element 3 to reduce the cutting of the first bonding wire 6A.

Since acrylic resin is included as a main component in the first adhesive layer 4, it is easy to satisfy the distance D1 larger than the distance D2 after the first adhesive layer 4 is deformed.

Before deforming of the first adhesive layer 4 in the adhering process, the first adhesive layer 4 has a sheet-shape. The first adhesive layer 4 with the sheet-shape preferably deforms to satisfy the distance D1 larger than the distance D2 during the adhering process.

To promote the intended deformation of the first adhesive layer 4 or other purpose, it is preferable to provide the one or more protrusions or a combination of the one or more protrusions and the one or more recesses on the circuit board 1 on an area where the first semiconductor element 3 is mounted and/or an area between the first pad 2A of the circuit board 1 and the region where the first semiconductor element 3 is mounted as shown in the schematic diagram of FIG. 15.

For the above reason(s), the one or more protrusions and the one or more recesses of the circuit board 1 are preferably in direct contact with the first adhesive layer 4.

In order to obtain the desired shape of the first adhesive layer 4, the first adhesive layer 4 may have a thick portion which protrudes toward the first pad 2A, the protrusion becomes thick from the first semiconductor element 3 side to the opposite side of the circuit board 1.

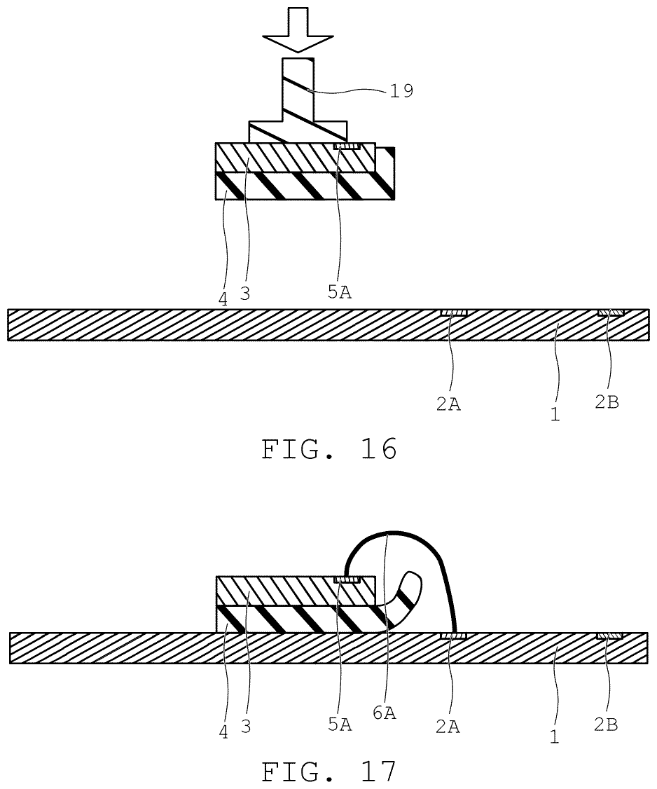

The forming the first bonding wire 6A which connects the first semiconductor element 3 and the circuit board 1 will be described with referring to the schematic diagram of FIG. 13. The first bonding wire 6A is formed as shown in FIG. 17. Subsequently, the second semiconductor element 7A is mounted, and other components are provided, resulting in the semiconductor device 100.

During the forming the first bonding wire 6A which connects the first semiconductor element 3 and the circuit board 1, the first bonding wire 6A is formed to stride over the first adhesive layer 4 at a position higher than the surface of the first semiconductor element 3 on the side opposite to the circuit board 1. At the time the first bonding wire 6A is formed, the distance D1 is longer than the distance D2

By adopting the manufacturing method for the semiconductor device 100 according to the embodiment, when forming the first bonding wire 6A that connects the first semiconductor element 3 to the circuit board 1, since the first adhesive layer 4 exists to hinder the first bonding wire 6A from contacting the outer periphery etc. of the first semiconductor element 3, it is possible to reduce the bonding wire from being crushed or fallen and contacting the outer periphery etc. of the first semiconductor element 3, or disconnection of the bonding wire during subsequent packaging processes. It contributes to improved reliability of the semiconductor device 100 according to this embodiment.

### Second Embodiment

A second embodiment relates to a semiconductor device and a manufacturing method for the same. The second embodiment is a variation of the first embodiment and will describe the differences.

FIG. 18 illustrates a schematic cross-sectional view of the semiconductor device 200 according to the second embodiment. Unlike the semiconductor device 100, a portion protruding from the first adhesive layer 4 is in direct contact with the first bonding wire 6A.

While a configuration of the semiconductor device 200 where the distance D1 is not longer than the distance D2 is applicable, the distance D1 is preferably longer than the distance D2.

The surface S2 of the first semiconductor element 3 on the opposite side of the circuit board 1 is preferably positioned on the circuit board 1 side rather than a position P3 where the first adhesive layer 4 is in direct contact with the first bonding wire 6A. In the stacking direction of the first adhesive layer 4 and the first semiconductor element 3, a distance D5 from the surface S2 (starting point) of the first semiconductor element 3 facing the opposite side of the circuit board 1 to the position P3 where the first adhesive layer 4 is in direct contact with the first bonding wire 6A is preferably 1 [μm] or more and 60 [μm] or less, more preferably 1 [μm] or more and 40 [μm] or less, and even more preferably 1 [μm] or more and 20 [μm] or less. By having a certain distance between the surface S2 of the first semiconductor element 3 and the position P3 where the first adhesive layer 4 is indirect contact with the first bonding wire 6A in the stacking direction of the first semiconductor element 3, it is possible to further reduce the bonding wire from contacting the outer periphery etc. of the first semiconductor element 3 or being disconnected.

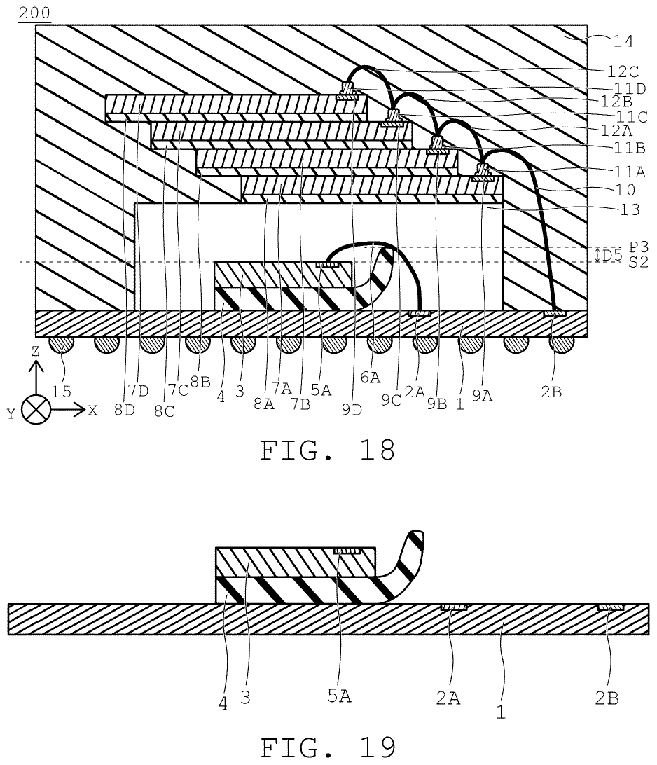

Next, the manufacturing method for the semiconductor device 200 will be described. Schematic diagrams illustrating the manufacturing method for the semiconductor device 200 are shown in FIGS. 19-21. A flowchart for the manufacturing method of the semiconductor device 200 according to the second embodiment can be referred to in FIG. 11.

The manufacturing method for the semiconductor device 200 includes adhering the first semiconductor element 3 on the circuit board 1 via the first adhesive layer 4, and forming the first bonding wire 6A which connects the first semiconductor element 3 and the circuit board 1. In the forming the first bonding wire 6A which connects the first semiconductor element 3 and the circuit board 1, the first bonding wire 6A is preferably formed so that the portion where the first adhesive layer 4 protrudes toward the first pad 2A side directly contacts the first bonding wire 6A.

Before deforming of the first adhesive layer 4 in the adhering process, the first adhesive layer 4 has a sheet-shape. The first adhesive layer 4 with the sheet-shape preferably deforms to satisfy the distance D1 larger than the distance D2 during the adhering process. Subsequently, the first bonding wire 6A is preferably formed so that the portion where the first adhesive layer 4 protrudes toward the first pad 2A side directly contacts the first bonding wire 6A.

Since acrylic resin is included as a main component in the first adhesive layer 4, it is easy to satisfy the distance D1 larger than the distance D2 when the first adhesive layer 4 is deformed. This allows the first bonding wire 6A to be easily directly contacted to the protrusion of the first adhesive layer 4.

Before deforming of the first adhesive layer 4 in the adhering process, the first adhesive layer 4 has a sheet-shape. The first adhesive layer 4 with the sheet-shape preferably deforms to satisfy the distance D1 larger than the distance D2 during the adhering process. This allows the first bonding wire 6A to be easily directly contacted to the protrusion of the first adhesive layer 4.

The semiconductor device 200 can be obtained by a process similar to that for the semiconductor device 100. By forming the first bonding wire 6A on the member shown in the schematic diagram of FIG. 19, obtaining the member shown in FIG. 20, and further providing the second semiconductor element 7A or the like, the semiconductor device 200 can be obtained.

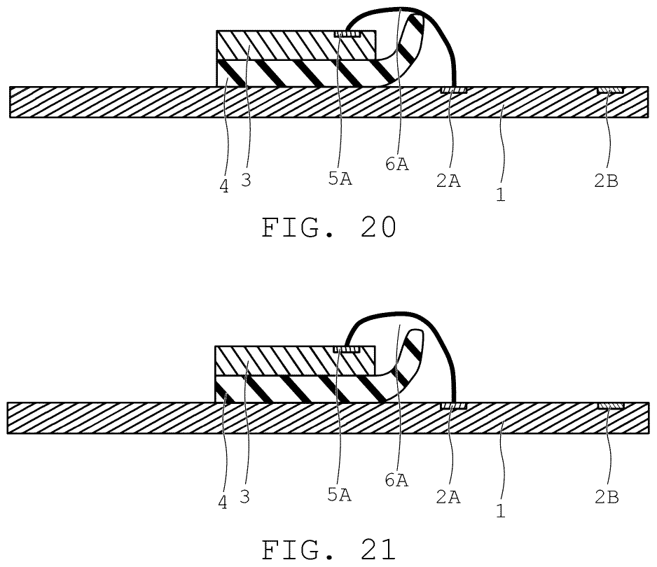

At the time of forming the first bonding wire 6A, the first bonding wire 6A may be in direct contact with the first adhesive layer 4. Or, the first bonding wire 6A deforms and may direct contact to the first adhesive layer 4 in which the first bonding wire 6A and the first adhesive layer 4 are separated when the first bonding wire 6A is formed as shown in the schematic diagram of FIG. 21, during subsequent process, for example, encapsulating the first semiconductor element 3. The first adhesive layer 4 supports the first bonding wire 6A, effectively preventing excessive deformation. This further suppresses contact with the periphery of the first semiconductor element 3 or disconnection of the bonding wire.

### Third Embodiment

A third embodiment relates to a semiconductor device and a manufacturing method for the same. The third embodiment is a variation of the first embodiment and will describe the differences between the first embodiment and the third embodiment.

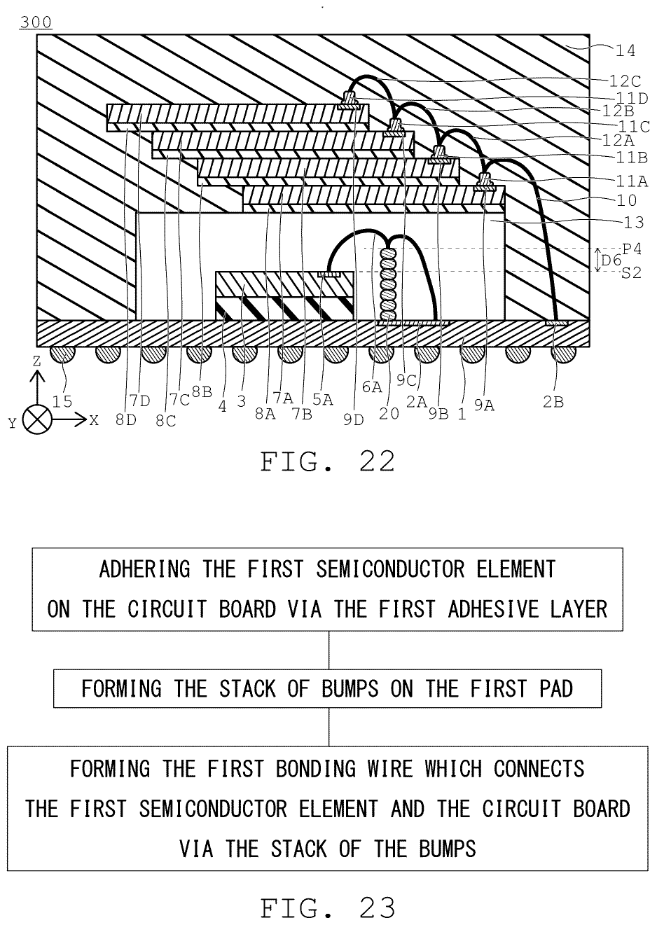

The semiconductor device 300 according to the third embodiment is shown in a schematic cross-sectional diagram of FIG. 22. Unlike the semiconductor device 100, it includes a stack of bumps 20 on the first pad 2A and the first bonding wire 6A connects the first pad 2A and the first semiconductor element 3 via the stack of the bumps 20

The first bonding wire 6A connects the first semiconductor element 3 to the circuit board 1 via (through relaying by) the bumps 20. The bumps 20 is provided preferably on the first pad 2A.

Since the bumps 20 are located between the connection surface between the first bonding wire 6A and the first semiconductor element 3 and the first pad 2A, the first bonding wire 6A is able to connect the first semiconductor element 3 and the circuit board 1 via the bumps 20.

The position (height of bump 20) P4 where the first bonding wire 6A is connected to the bumps 20 in the stacking direction of the first adhesive layer 4 and the first semiconductor element 3 is preferably apart from the circuit board 1, further than the side opposite to the circuit board 1 of the first semiconductor element 3.

A distance D6 between the position P4 (starting point) where the first bonding wire 6A and the bumps 20 are connected and the surface S2 (ending point) opposite to the circuit board 1 of the first semiconductor element 3, in the stacking direction of the first adhesive layer 4 and the first semiconductor element 3, is preferably 1 [μm] or more and 60 [μm] or less, more preferably 1 [μm] or more and 40 [μm] or less, and further preferably 1 [μm] or more and 20 [μm] or less.

The first adhesive layer 4 of the first embodiment or the second embodiment may be used in the third embodiment.

Also in the third embodiment, the contact between the first bonding wire 6A and the periphery of the first semiconductor element 3 is hindered. By suppressing the contact between the first bonding wire 6A and the periphery of the first semiconductor element 3, it is possible to prevent the first bonding wire 6A from falling over or disconnecting, which contributes to improved reliability of the semiconductor device 300.

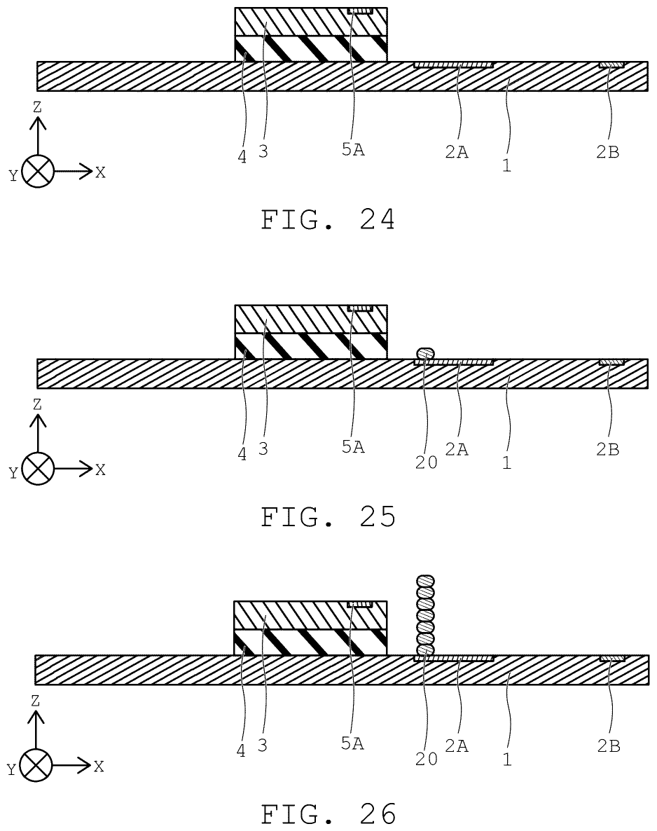

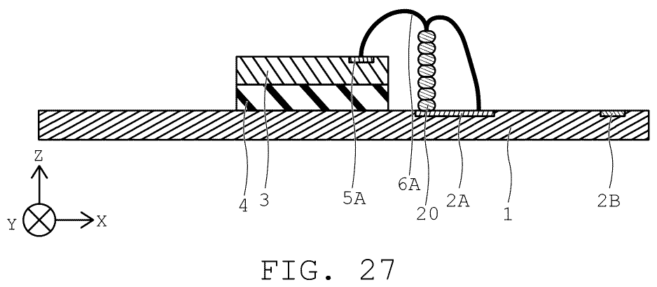

Next, a manufacturing method for the semiconductor device 300 will be described. FIG. 23 shows a flowchart of the manufacturing method for the semiconductor device 300. FIG. 24, FIG. 25, FIG. 26, and FIG. 27 show schematic diagrams relating to manufacturing method for the semiconductor device 300.

The manufacturing method for the semiconductor device 300 includes adhering the first semiconductor element 3 on the circuit board 1 via the first adhesive layer 4, forming the stack of bumps 20 on the first pad 2A, and forming the first bonding wire 6A which connects the first semiconductor element 3 and the circuit board 1 via the stack of the bumps 20.

Referring to FIG. 24 for the s adhering the first semiconductor element 3 on the circuit board 1 via the first adhesive layer 4 will be described. The laminated body of the first semiconductor element 3 and the first adhesive layer (pre-cured) 4 mounted on the jig 19 (e.g., collet), is pressed onto the circuit board 1 to place the laminated body on the circuit board 1, resulting in the member shown in the schematic diagram of FIG. 24. At this time, the portion of the first adhesive layer 4 protrudes toward the first pad 2A (the portion on the first pad 2A side extending in a direction to the second pad 5A from the center of the first semiconductor element 3, which is not directly in contact with the first semiconductor element 3) may or may not exist. The first pad 2A is preferably a large-area pad extending towards the side of the first semiconductor element 3 for forming the bumps 20.

Referring to FIG. 25 and FIG. 26, the forming the stacked bumps 20 on the first pad 2A will be described. The bumps 20 are formed on the side of the first semiconductor element 3 of the first pad 2A to obtain the member shown in FIG. 25. Then, multiple bumps 20 are piled up on top of the bump(s) 20, resulting in a member with the stack of the bumps 20 formed on the first pad 2A as shown in FIG. 26.

Referring to FIG. 27, the forming the first bonding wire 6A which connects the first semiconductor element 3 and the circuit board 1 via the stack of the bumps 20. The first bonding wire 6A is formed on the member shown in FIG. 26. The first bonding wire 6A connects the first semiconductor element 3 and the circuit board 1, relaying on the top surface of the stack of the bumps 20 without directly connecting the first pad 2A and the second pad 5A of the first semiconductor element 3, resulting in the member shown in FIG. 27. Further mounting of the second semiconductor element 7A and other steps are processed, resulting in the semiconductor device 300.

By virtue of the bumps 20 supporting the first bonding wire 6A, the large deformation of the first bonding wire 6A is hindered, which further prevents the contact between the first bonding wire 6A and the periphery of the first semiconductor element 3 and wire breakage.

Hereinafter, technical clauses of embodiments are additionally noted.

Clause 1. A semiconductor device comprising:
a circuit board;
a first semiconductor element provided on the circuit board via a first adhesive layer; and
a first bonding wire connecting the circuit board and the first semiconductor element, wherein
a first distance is longer than a second distance,
the first distance is a length between a connection surface between the first adhesive layer and the first semiconductor element and a location on the first adhesive layer on the furthest opposite side of the circuit board, and
the second distance is a length between a surface of the first semiconductor element on the opposite side of the circuit board and the connection surface between the first adhesive layer and the first semiconductor element.

Clause 2. The semiconductor device according clause 1, wherein
a difference between the first distance and the second distance is 1 [μm] or more and 60 [μm] or less.

Clause 3. The semiconductor device according to clause 1, or 2 wherein
a thickness of the first adhesive layer is 1 times or more and 5 times or less a thickness of the first semiconductor element.

Clause 4. The semiconductor device according to any one of clauses 1 to 3, wherein
the first adhesive layer comprises acrylic resin as a main component.

Clause 5. The semiconductor device according to any one of clauses 1 to 4, wherein
the first adhesive layer comprises 20 [wt %] or more of acrylic resin.

Clause 6. The semiconductor device according to any one of clauses 1 to 5, wherein
the first adhesive layer is in direct contact with an edge of the surface of the first semiconductor element on the opposite side of the circuit board.

Clause 7. The semiconductor device according to any one of clauses 1 to 6, wherein
the circuit board comprises a recess and/or a protrusion on the side where the first adhesive layer is provided.

Clause 8. A semiconductor device comprising:
a circuit board comprising a first pad;
a semiconductor element provided on the circuit board via a first adhesive layer; and
a first bonding wire connecting the circuit board and the first semiconductor element, wherein
the first adhesive layer comprises a portion which does not overlap with the first semiconductor on the first pad side in a stacking direction of the first adhesive layer and the first semiconductor element, and
the first bonding wire is in direct contact with the first adhesive layer.

Clause 9. The semiconductor device according to any one of clauses 8, wherein
the first adhesive layer comprises acrylic resin as a main component.

Clause 10. The semiconductor device according to clause 8 or 9, wherein
the first adhesive layer comprises 20 [wt %] or more of acrylic resin.

Clause 11. The semiconductor device according to any one of clauses 8 to 10, wherein
the circuit board comprises a recess and/or a protrusion on the side where the first adhesive layer is provided.

Clause 12. The semiconductor device according to any one of clauses 8 to 11, wherein
a surface of the first semiconductor element on the opposite side of the circuit board is located on the circuit board side, relative to a position where the first bonding wire is in direct contact with the first adhesive layer.

Clause 13. The semiconductor device according to any one of clauses 8 to 12, wherein
a first distance is longer than a second distance,
the first distance is a length between a connection surface between the first adhesive layer and the first semiconductor element and a location on the first adhesive layer on the furthest opposite side of the circuit board, and
the second distance is a length between a surface of the first semiconductor element on the opposite side of the circuit board and the connection surface between the first adhesive layer and the first semiconductor element.

Clause 14. The semiconductor device according to any one of clauses 8 to 13, wherein
a distance between a surface of the first semiconductor element on the opposite side of the circuit board and a position where the first bonding wire is in direct contact with the first adhesive layer in the stacking direction of the first adhesive layer and the first semiconductor element is 1 [μm] or more and 60 [μm] or less.

Clause 15. A manufacturing method for a semiconductor device comprising:
adhering a first semiconductor element on a circuit board via a first adhesive layer; and
forming a first bonding wire which connects the first semiconductor element and the circuit board, wherein p1 the adhering is procced so that a first distance becomes longer than a second distance, p1 the first distance is a length between a connection surface between the first adhesive layer and the first semiconductor element and a location on the opposite side of the first adhesive layer on the furthest opposite side of the circuit board, and
the second distance is a length between a surface of the first semiconductor element on the opposite side of the circuit board and the connection surface between the first adhesive layer and the first semiconductor element.

Clause 16. The manufacturing method according to clause 15, wherein
the first adhesive layer comprises acrylic resin as a main component.

Clause 17. The manufacturing method according to clause 15 or 16, wherein
the first adhesive layer comprises 20 [wt %] or more of acrylic resin.

Clause 18. The manufacturing method according to any one of clauses 15 to 17, wherein
the first adhesive layer deforms from a sheet-shape to a shape which satisfy the first distance is longer than the second distance.

Clause 19. A semiconductor device comprising:
a circuit board comprising a first pad;
a semiconductor element provided on the circuit board via a first adhesive layer;
a first bonding wire connecting the first pad and the first semiconductor element; and
a stack of bumps on the first pad, wherein
the first bonding wire connects the first pad and the first semiconductor element via the stack of the bumps, and
the stack of the bumps is located between the first semiconductor element and the connection surface between the first adhesive layer and the first semiconductor element.

Clause 20. The semiconductor device according to clause 19,
wherein a position where the stack of the bump and the first bonding wire is located farther apart from the circuit board to a surface of the first semiconductor element on the opposite side of the circuit board in a stacking direction of the first adhesive layer and the first semiconductor element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device comprising:
a circuit board;
a first semiconductor element provided on the circuit board via a first adhesive layer; and
a first bonding wire connecting the circuit board and the first semiconductor element, wherein
a first distance is longer than a second distance,
the first distance is a length between a connection surface between the first adhesive layer and the first semiconductor element and a location on the first adhesive layer on the furthest opposite side of the circuit board, and
the second distance is a length between a surface of the first semiconductor element on the opposite side of the circuit board and the connection surface between the first adhesive layer and the first semiconductor element.

2. The semiconductor device according claim 1, wherein
a difference between the first distance and the second distance is 1 [μm] or more and 60 [μm] or less.

3. The semiconductor device according to claim 1, wherein
a thickness of the first adhesive layer is 1 times or more and 5 times or less a thickness of the first semiconductor element.

4. The semiconductor device according to claim 1, wherein
the first adhesive layer comprises acrylic resin as a main component.

5. The semiconductor device according to claim 1, wherein
the first adhesive layer comprises 20 [wt %] or more of acrylic resin.

6. The semiconductor device according to claim 1, wherein
the first adhesive layer is in direct contact with an edge of the surface of the first semiconductor element on the opposite side of the circuit board.

7. The semiconductor device according to claim 1, wherein
the circuit board comprises a recess and/or a protrusion on the side where the first adhesive layer is provided.

8. A semiconductor device comprising:
a circuit board comprising a first pad;
a semiconductor element provided on the circuit board via a first adhesive layer; and
a first bonding wire connecting the circuit board and the first semiconductor element, wherein
the first adhesive layer comprises a portion which does not overlap with the first semiconductor on the first pad side in a stacking direction of the first adhesive layer and the first semiconductor element, and
the first bonding wire is in direct contact with the first adhesive layer.

9. The semiconductor device according to claim 8, wherein
the first adhesive layer comprises acrylic resin as a main component.

10. The semiconductor device according to claim 8, wherein
the first adhesive layer comprises 20 [wt %] or more of acrylic resin.

11. The semiconductor device according to claim 8, wherein
the circuit board comprises a recess and/or a protrusion on the side where the first adhesive layer is provided.

12. The semiconductor device according to claim 8, wherein
a surface of the first semiconductor element on the opposite side of the circuit board is located on the circuit board side, relative to a position where the first bonding wire is in direct contact with the first adhesive layer.

13. The semiconductor device according to claim 8, wherein
a first distance is longer than a second distance,
the first distance is a length between a connection surface between the first adhesive layer and the first semiconductor element and a location on the first adhesive layer on the furthest opposite side of the circuit board, and
the second distance is a length between a surface of the first semiconductor element on the opposite side of the circuit board and the connection surface between the first adhesive layer and the first semiconductor element.

14. The semiconductor device according to claim 8, wherein
a distance between a surface of the first semiconductor element on the opposite side of the circuit board and a position where the first bonding wire is in direct contact with the first adhesive layer in the stacking direction of the first adhesive layer and the first semiconductor element is 1 [μm] or more and 60 [μm] or less.

15. A manufacturing method for a semiconductor device comprising:
adhering a first semiconductor element on a circuit board via a first adhesive layer; and
forming a first bonding wire which connects the first semiconductor element and the circuit board, wherein
the adhering is procced so that a first distance becomes longer than a second distance,
the first distance is a length between a connection surface between the first adhesive layer and the first semiconductor element and a location on the opposite side of the first adhesive layer on the furthest opposite side of the circuit board, and
the second distance is a length between a surface of the first semiconductor element on the opposite side of the circuit board and the connection surface between the first adhesive layer and the first semiconductor element.

16. The manufacturing method according to claim 15, wherein
the first adhesive layer comprises acrylic resin as a main component.

17. The manufacturing method according to claim 15, wherein
the first adhesive layer comprises 20 [wt %] or more of acrylic resin.

18. The manufacturing method according to claim 15, wherein
the first adhesive layer deforms from a sheet-shape to a shape which satisfy the first distance is longer than the second distance.
